(19) United States
(12) Patent Application Publication
(10) Pub. No.: US 2025/0386639 A1
(43) Pub. Date: Dec. 18, 2025

(54) DISPLAY DEVICE, METHOD OF MANUFACTURING DISPLAY DEVICE, AND ELECTRONIC DEVICE COMPRISING DISPLAY DEVICE

(71) Applicant: Samsung Display Co., LTD., Yongin-si (KR)

(72) Inventors: Byoung Yong KIM, Yongin-si (KR); Jae Gwang UM, Yongin-si (KR); Tae Hee LEE, Yongin-si (KR); Moon Won CHANG, Yongin-si (KR)

(73) Assignee: Samsung Display Co., LTD., Yongin-si (KR)

(21) Appl. No.: 19/093,942

(22) Filed: Mar. 28, 2025

(30) Foreign Application Priority Data
Jun. 18, 2024 (KR) 10-2024-0079055
Jun. 28, 2024 (KR) 10-2024-0085004

(51) Int. Cl. H10H 29/49; H10H 29/01; H10H 29/80

(52) U.S. Cl. CPC H10H 29/49; H10H 29/012; H10H 29/032; H10H 29/8322

(57) ABSTRACT

Provided is a display device including a substrate; an anode electrode and a cathode electrode on the substrate; an intermediate electrode including a first intermediate electrode disposed on the anode electrode and exposes a portion of the anode electrode, and a second intermediate electrode disposed on the cathode electrode and exposes a portion of the cathode electrode; and a light-emitting element including a first element electrode electrically connected to the anode electrode, and a second element electrode electrically connected to the cathode electrode.

### CROSS-REFERENCE TO RELATED PATENT APPLICATION(S)

This application claims priority to and the benefits of Korean Patent Application No. 10-2024-0079055 under 35 U.S.C. § 119, filed on Jun. 18, 2024, and Korean Patent Application No. 10-2024-0085004 under 35 U.S.C. § 119, filed on Jun. 28, 2024, in the Korean Intellectual Property Office, the entire contents of which are incorporated herein by references.

### BACKGROUND

### 1. Technical Field

The disclosure generally relates to a display device, a method of manufacturing the display device, and an electronic device comprising the display device. More particularly, the disclosure relates to a display device capable of improving the reliability of an inspection process for a light-emitting.

### 2. Description of the Related Art

Recently, as interest in information displays increases, research and development of display devices has been carried out continuously. A display device is manufactured on the basis of multiple process steps. In order to ensure the reliability of operation of the display device, it may be necessary to carry out an inspection process on the display device.

### SUMMARY

One aspect of the disclosure is to provide a display device which improves the reliability of an inspection process for a light-emitting element and has an excellent display quality, a method of manufacturing the display device, and an electronic device comprising the display device.

A display device according to an embodiment of disclosure may include: a substrate; an anode electrode and a cathode electrode, which are disposed on the substrate; an intermediate electrode including a first intermediate electrode which is disposed on the anode electrode and exposes a portion of the anode electrode, and a second intermediate electrode which is disposed on the cathode electrode and exposes a portion of the cathode electrode; and a light-emitting element including a first element electrode electrically connected to the anode electrode, and a second element electrode electrically connected to the cathode electrode. The first element electrode may include a first transparent electrode layer and a first bonding electrode layer on the first transparent electrode layer. The second element electrode may include a second transparent electrode layer and a second bonding electrode layer on the second transparent electrode layer. The first bonding electrode layer may be disposed between the first transparent electrode layer and the first intermediate electrode and contacts the portion of the anode electrode exposed by the first intermediate electrode. The second bonding electrode layer may be disposed between the second transparent electrode layer and the second intermediate electrode and contacts the portion of the cathode electrode exposed by the second intermediate electrode.

According to an embodiment, the first intermediate electrode may be at least partially disposed on a portion of the anode electrode. The second intermediate electrode may be at least partially disposed on a portion of the cathode electrode.

According to an embodiment, a side surface of a first portion of the intermediate electrode may face a side surface of a second portion of the intermediate electrode.

According to an embodiment, the intermediate electrode may form a concavo-convex structure on the anode electrode and the cathode electrode.

According to an embodiment, the intermediate electrode may include one or more of copper (Cu), gold (Au), and silver (Ag).

According to an embodiment, the first bonding electrode layer may be electrically connected to the first intermediate electrode and the anode electrode. The second bonding electrode layer may be electrically connected to the second intermediate electrode and the cathode electrode.

According to an embodiment, the first bonding electrode layer may be directly adjacent to an inner side surface of the first intermediate electrode. The second bonding electrode layer may be adjacent to an inner side surface of the second intermediate electrode.

According to an embodiment, an opening is formed in the intermediate electrode. The first bonding electrode layer and the second bonding electrode layer may fill at least a portion of the opening.

According to an embodiment, the first bonding electrode layer may cover an area of more than about 30% of an upper surface of the anode electrode. The second bonding electrode layer may cover an area of more than about 30% of an upper surface of the cathode electrode.

According to an embodiment, the first bonding electrode layer and the second bonding electrode layer may have a lower melting point than a melting point of the intermediate electrode.

According to embodiments, the first transparent electrode layer and the second transparent electrode layer may include one or more of Indium Tin Oxide (ITO) and Indium Zinc Oxide (IZO).

According to an embodiment, the intermediate electrode may include a plurality of intermediate electrodes which are spaced apart from each other and arranged in a matrix shape, and have an island shape.

According to an embodiment, the intermediate electrode may have a mesh shape, and include first portions extending in a first direction and second portions extending in a second direction intersecting the first direction.

According to an embodiment, the light-emitting element may be a flip-chip type light-emitting element.

A method of manufacturing a display device according to an embodiment of disclosure may include: patterning an anode electrode and a cathode electrode on a substrate; patterning a first intermediate electrode and a second intermediate electrode on the anode electrode and the cathode electrode, respectively; disposing a light-emitting element including a first element electrode on the first intermediate electrode and a second element electrode on the second intermediate electrode; and inspecting the light-emitting element. The patterning of the first intermediate electrode may include exposing a portion of the anode electrode by the first intermediate electrode. The patterning of the second intermediate electrode may include exposing a portion of the cathode electrode by the second intermediate electrode. The inspecting of the light-emitting element may include determining whether or not the light-emitting element is normally disposed, without light emission of the light-emitting element.

According to embodiments, the patterning of the first intermediate electrode may include forming an opening by forming a concavo-convex structure by the first intermediate electrode. The patterning of the second intermediate electrode may include forming an opening by forming a concavo-convex structure by the second intermediate electrode.

According to an embodiment, the light-emitting element may include a first element electrode including a first bonding electrode layer and a first transparent electrode layer and a second element electrode including a second bonding electrode layer and a second transparent electrode layer. The disposing of the light-emitting element may include: melting the first bonding electrode layer to fill the opening on the anode electrode; and melting the second bonding electrode layer to fill the opening on the cathode electrode.

According to an embodiment, the inspecting of the light-emitting element may include acquiring, by an optical inspection device, image information which includes an image showing an extent to which the first bonding electrode layer covers the anode electrode and the first intermediate electrode and an image showing an extent to which the second bonding electrode layer covers the cathode electrode and the second intermediate electrode. The image information may be provided by transmitting through the first transparent electrode layer and the second transparent electrode layer.

According to an embodiment, the inspecting of the light-emitting element may include determining whether the first bonding electrode layer is normally bonded to the anode electrode and the first intermediate electrode, based on an extent to which the first bonding electrode layer fills the opening on the anode electrode.

According to an embodiment, the determining of whether the first bonding electrode layer is normally bonded to the anode electrode and the first intermediate electrode may include determining that the first bonding electrode layer is normally bonded to a first anode electrode and the first intermediate electrode, in case that the first bonding electrode layer fills an area including the opening on the anode electrode beyond a selected range.

An electronic device according to an embodiment of disclosure may include: a substrate; an anode electrode and a cathode electrode, which are disposed on the substrate; an intermediate electrode including a first intermediate electrode which is disposed on the anode electrode and exposes a portion of the anode electrode, and a second intermediate electrode which is disposed on the cathode electrode and exposes a portion of the cathode electrode; and a light-emitting element including a first element electrode electrically connected to the anode electrode, and a second element electrode electrically connected to the cathode electrode. The first element electrode may include a first transparent electrode layer and a first bonding electrode layer on the first transparent electrode layer. The second element electrode may include a second transparent electrode layer and a second bonding electrode layer on the second transparent electrode layer. The first bonding electrode layer may be disposed between the first transparent electrode layer and the first intermediate electrode and contacts the portion of the anode electrode exposed by the first intermediate electrode. The second bonding electrode layer may be disposed between the second transparent electrode layer and the second intermediate electrode and contacts the portion of the cathode electrode exposed by the second intermediate electrode.

According to embodiments of the disclosure, it is possible to provide a display device, which improves the reliability of an inspection process for a light-emitting element and has an excellent display quality, a method of manufacturing the display device, and an electronic device comprising the display device.

### BRIEF DESCRIPTION OF THE DRAWINGS

FIG. 1 is a schematic plan view schematically illustrating a display device according to an embodiment.

FIG. 2 is a schematic cross-sectional diagram schematically illustrating a display device according to an embodiment.

FIG. 3 is a schematic cross-sectional diagram schematically illustrating a display device according to an embodiment.

FIG. 4 is a schematic plan view schematically illustrating pixels according to an embodiment.

FIG. 5 is a schematic cross-sectional diagram schematically illustrating a light-emitting element according to an embodiment.

FIG. 6 is a schematic cross-sectional diagram schematically illustrating a display device according to an embodiment.

FIG. 7 is a schematic cross-sectional diagram schematically illustrating a display device according to an embodiment.

FIGS. 8 and 9 are schematic plan views schematically illustrating the structure in which an intermediate electrode is arranged on an anode electrode and a cathode electrode according to an embodiment.

FIG. 10, FIG. 11, FIG. 13, and FIG. 14 are schematic cross-sectional diagrams for respective process steps schematically illustrating a method of manufacturing a display device according to an embodiment.

FIG. 12 is a schematic plan view schematically illustrating an inspection step for a display device in a method of manufacturing the display device according to an embodiment.

FIG. 15 is a schematic block diagram illustrating an embodiment of an electronic device.

FIGS. 16 to 19 are schematic perspective views illustrating examples of application of the electronic device in FIG. 15.

### DETAILED DESCRIPTION OF THE EMBODIMENTS

The disclosure may be variously altered and may take many forms, and specific embodiments are illustrated in drawings and described in detail in the detailed description. However, it is not intended to limit the disclosure to any particular form of disclosure and should be understood to include all changes, equivalents or substitutions that fall within the scope of ideas and technology of the disclosure.

Terms such as first and second may be used to describe various components, but the components should not be limited by the above terms. The above terms are used only for the purpose of distinguishing one component from another. For example, a first component may be named a second component without going beyond the scope of rights of the disclosure, and similarly, the second component may be named the first component. Singular expressions include plural expressions, unless the context clearly means otherwise.

In the disclosure, the terms “include” or “have” shall be understood to designate the existence of a feature, a number, a step, an action, a component, a part, or a combination thereof set forth in the disclosure, and shall be understood not to preclude the possibility of the existence or addition of one or more other features or numbers, steps, motions, components, parts, or combinations thereof. In case that a portion such as a layer, a film, an area, or a plate is referred to as being “on” another part, this includes not only the case where the portion is “directly on top” of the other part, but also the case where there is still another portion in between. In the present specification, in case that a portion such as a layer, a film, an area, or a plate is referred to as being formed on another part, the direction in which the portion is formed is not limited to an upward direction, but includes formation in a lateral or downward direction. Conversely, in case that a portion such as a layer, a film, an area, or a plate is referred to as being “below” another part, this includes not only the case where the portion is “just below” the other part, but also the case where there is still another portion in between.

This disclosure relates to a display device, a method of manufacturing the display device, and an electronic device comprising the display device. Hereinafter, a display device, a method of manufacturing the display device, and an electronic device comprising the display device will be described with reference to the accompanying drawings.

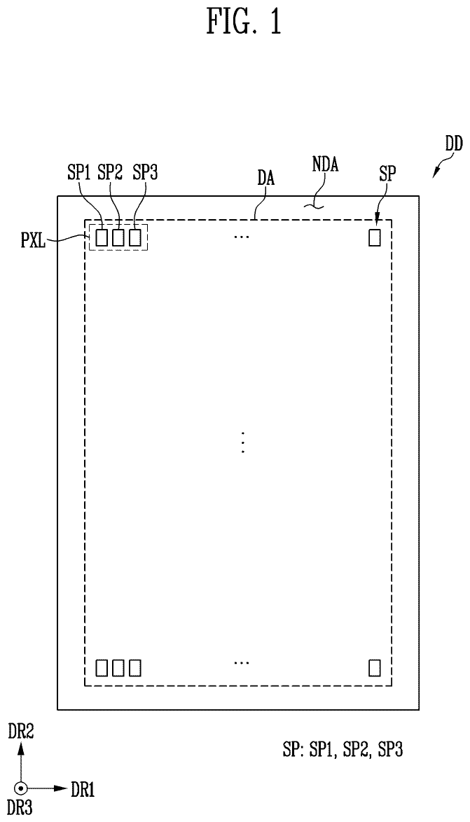

FIG. 1 is a schematic plan view schematically illustrating a display device according to an embodiment.

Referring to FIG. 1, a display device DD emits light. The display device DD may include a display area DA and a non-display area NDA. The display device DD displays an image through the display area DA. The non-display area NDA is disposed on the periphery of the display area DA.

The display device DD includes sub-pixels SP in the display area DA. The sub-pixels SP may be arranged in a first direction DR1 and a second direction DR2 intersecting the first direction DR1. For example, the sub-pixels SP may be arranged in a matrix form in the first direction DR1 and the second direction DR2. As another example, the sub-pixels SP may be arranged in a zigzag pattern in the first direction DR1 and the second direction DR2. The arrangement of the sub-pixels SP may vary according to embodiments. The first direction DR1 may be a row direction, and the second direction DR2 may be a column direction.

Two or more sub-pixels of multiple sub-pixels SP may form a single pixel PXL. In FIG. 1, a pixel PXL is shown to include three sub-pixels SP1 to SP3, but embodiments are not limited thereto. For example, a pixel PXL may include two sub-pixels. Hereinafter, for the convenience of explanation, it is assumed that a pixel PXL (or sub-pixels SP) includes first to the third sub-pixels SP1 to SP3.

Each of first to third sub-pixels SP1 to SP3 may generate one of a variety of colors such as red, green, blue, cyan, magenta, yellow, etc. For the sake of clarity and convenience of explanation, it is assumed that the first sub-pixel SP1 generates light of red color, the second sub-pixel SP2 generates light of green color, and the third sub-pixel SP3 generates light of blue color.

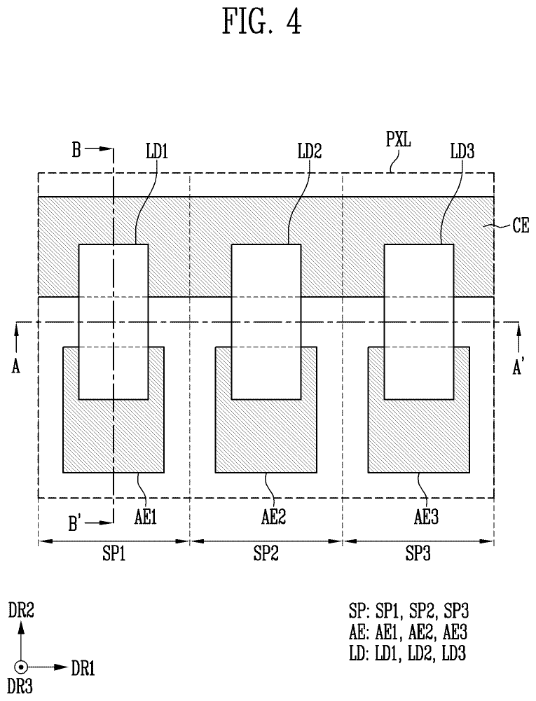

Each of the first to third sub-pixels SP1 to SP3 may include at least one light-emitting element LD configured to generate light (see FIG. 4). In other embodiments, the light-emitting elements LD of the first to third sub-pixels SP1 to SP3 may generate light of the same color. For example, the light-emitting elements of the first to third sub-pixels SP1 to SP3 may generate light of blue color. In other embodiments, the light-emitting elements of the first to third sub-pixels SP1 to SP3 may generate light of different colors. For example, the light-emitting elements of the first to third sub-pixels SP1 to SP3 may generate red, green, and blue light, respectively.

As a display device DD, an LED display panel may be used, which uses a microscale or nanoscale light-emitting diode as the light-emitting element LD.

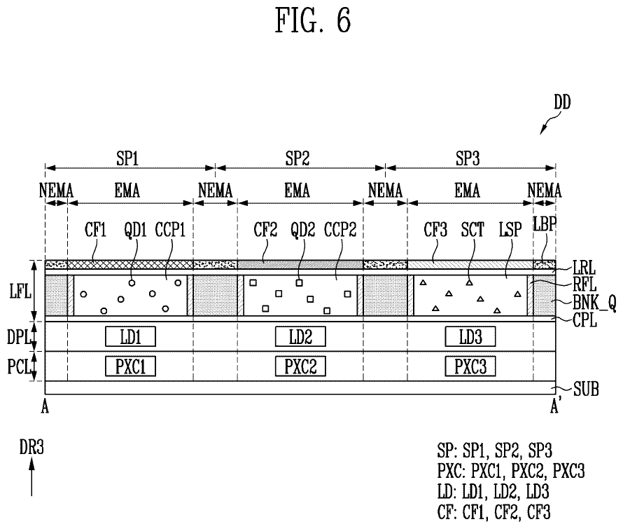

In the non-display area NDA, a component for controlling the sub-pixels SP may be disposed. Wirings electrically connected to the sub-pixels SP, such as a gate line, a data line, a power line, and a pixel control line, electrically connected to pixel circuits PXC for driving the sub-pixels SP (see FIG. 6), may be arranged in the non-display area NDA. A gate driver, a data driver, a voltage generator, a controller, etc. for operating the sub-pixels SP may be disposed in the non-display area NDA.

In other embodiments, the display area DA may have a variety of shapes. The display area DA may have a shape of a closed loop including straight and/or curved sides. For example, a display area DA may have shapes such as polygons, circles, semicircles, ellipses, etc.

In other embodiments, the display device DD may have a flat display surface. In other embodiments, the display device DD may have at least a partially rounded display surface. In other embodiments, the display device DD may be bendable, foldable, or rollable. For example, the display device DD and/or the substrate of the display device DD may include materials having flexible properties.

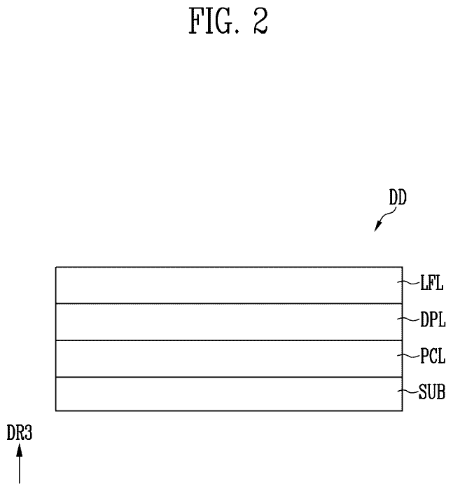

FIG. 2 is a schematic cross-sectional diagram schematically illustrating a display device according to an embodiment.

Referring to FIG. 2, the display device DD may include a substrate SUB, and a pixel circuit layer PCL, a display element layer DPL, and a light functional layer LFL that are sequentially stacked on the substrate SUB in a third direction DR3 intersecting the first and second directions DR1 and DR2.

The substrate SUB may be formed of an insulating material such as glass or resin. For example, the substrate SUB may include a glass substrate. As another example, the substrate SUB may include a polyimide substrate. As another example, the substrate SUB may include a silicon wafer substrate formed using semiconductor processes. In other embodiments, the substrate may be made of a flexible material that allows bending or folding, and may have a single-layer structure or a multi-layered structure.

The pixel circuit layer PCL is disposed on the substrate SUB. The pixel circuit layer PCL may include insulation layers, and semiconductor patterns and conductive patterns disposed between the insulation layers. Conductive patterns in the pixel circuit layer PCL may function as circuit elements, wirings, and the like.

The pixel circuit layer PCL may include a pixel circuit PXC. The pixel circuit PXC may be provided as transistors and one or more capacitors.

The wirings of the pixel circuit layer PCL may include wirings electrically connected to the sub-pixels SP. The wirings of the pixel circuit layer PCL may include various signal lines and/or voltage lines required to drive the display element layer DPL.

The display element layer DPL is disposed on the pixel circuit layer PCL. The display element layer DPL may include light-emitting elements LD of sub-pixels SP.

The light functional layer LFL may be disposed on the display element layer DPL. The light functional layer LFL may include light conversion pattern layers CCP1 and CCP2 (see FIG. 6) including color conversion particles QD1 and QD2 (see FIG. 6) and/or scattering particles SCT (see FIG. 6) (see FIG. 6). For example, the color conversion particles QD1 and QD2 may include quantum dots. The quantum dots may change the wavelength (or color) of light emitted from the display element layer DPL. The light functional layer LFL may further include light scattering pattern layers (LSP) with scattering particles (SCT) that scatter the provided light. In other embodiments, the light conversion pattern layers CCP1 and CCP2 and the light scattering pattern layers LSP may be omitted.

The light functional layer LFL may further include color filters CF (see FIG. 6). The color filters CF may selectively transmit light of a specific wavelength (or a specific color). In other embodiments, the color filter CF may be omitted.

A window may be provided on the light functional layer LFL to protect the exposed surface (or top) of the display device DD. The window may protect the display device DD from external shocks. The window may be bonded to the light functional layer LFL via an optically transparent adhesive member. The window may have a multi-layer structure selected from a glass substrate, a plastic film, or a plastic substrate. These multi-layered structures may be formed through a continuous process or an adhesive process using an adhesive layer. The whole or portion of the window may be flexible.

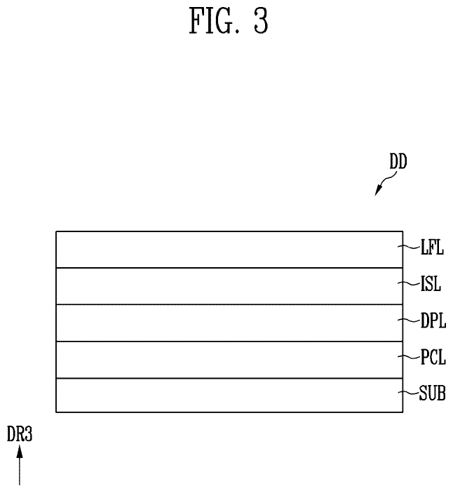

FIG. 3 is a schematic cross-sectional diagram schematically illustrating a display device according to an embodiment.

Referring to FIG. 3, the display device DD may include a substrate SUB, a pixel circuit layer PCL, a display element layer DPL, an input sensing layer ISL, and a light functional layer LFL. For example, the input sensing layer ISL may be disposed between the display element layer DPL and the light functional layer LFL. The substrate SUB, the pixel circuit layer PCL, the display element layer DPL, and the light functional layer LFL are configured in the same manner as in the substrate SUB, the pixel circuit layer PCL, the display element layer DPL, and the light functional layer LFL described with reference to FIG. 2. Hereinafter, redundant explanations are omitted.

The input sensing layer ISL may sense a user input to the upper surface (or display surface) of the display device DD. The input sensing layer ISL may sense external objects such as a user's hand, pen, etc. For example, the input sensing layer ISL may include touch electrodes.

Referring to FIGS. 4 to 9, the display device DD including a light-emitting element LD according to an embodiment is described. For the convenience of explanation, information that may overlap the above-described information may be briefly explained or may not be repeated.

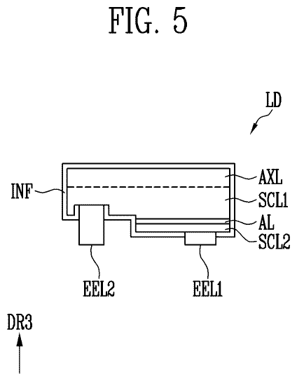

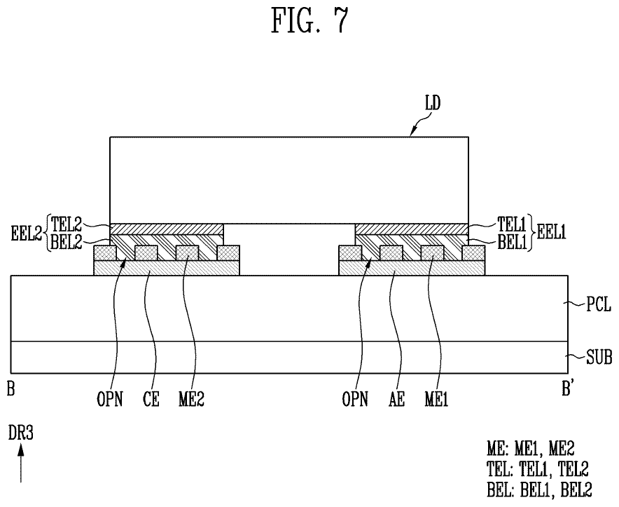

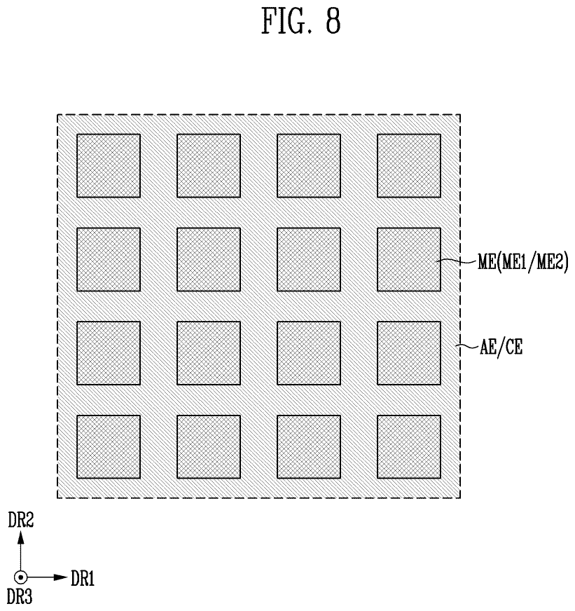

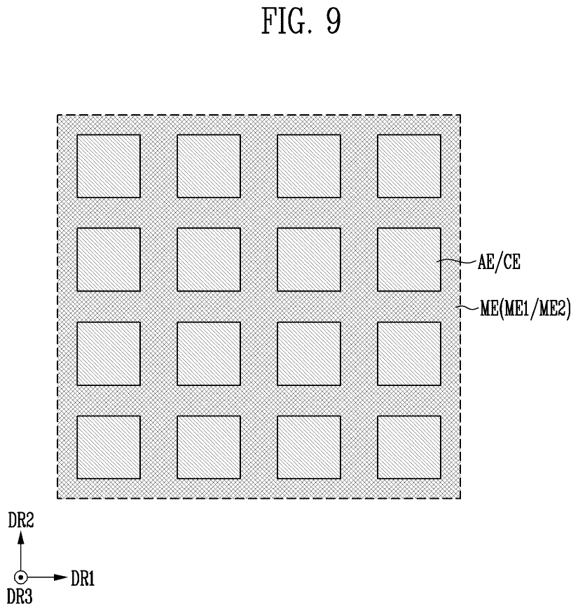

FIG. 4 is a schematic plan view schematically illustrating the pixels according to an embodiment. FIG. 5 is a schematic cross-sectional diagram schematically illustrating a light-emitting element according to an embodiment. FIG. 6 is a schematic cross-sectional diagram schematically illustrating a display device according to an embodiment. FIG. 6 is a schematic cross-sectional diagram taken along line A-A′ of FIG. 4. FIG. 7 is a cross-sectional diagram schematically illustrating a display device according to an embodiment. FIG. 7 is a schematic cross-section taken along line B-B′ in FIG. 4. FIGS. 8 and 9 are plan views schematically illustrating the structure in which an intermediate electrode is arranged on an anode electrode and a cathode electrode according to an embodiment.

Referring to FIGS. 4 to 6, the pixel PXL may include first to third sub-pixels SP1 to SP3. The first to third sub-pixels SP1 to SP3 may be arranged in a first direction DR1. However, the arrangement of pixels PXL is not limited to this and may vary in other embodiments.

The pixel PXL may include an anode electrode AE. The anode electrode AE may include a first anode electrode AE1 disposed on the first sub-pixel SP1, a second anode electrode AE2 disposed on the second sub-pixel SP2, and a third anode electrode AE3 disposed on the third sub-pixel SP3.

The first anode electrode AE1 may be electrically connected to the first pixel circuit PXC1, which is the pixel circuit PXC of the first sub-pixel SP1. The second anode electrode AE2 may be electrically connected to the second pixel circuit PXC2, which is the pixel circuit PXC of the second sub-pixel SP2. The third anode electrode AE3 may be electrically connected to a third pixel circuit PXC3, which is the pixel circuit PXC of the third sub-pixel SP3.

The first to third anode electrodes AE1 to AE3 may be disposed in the first direction DR1 and may be spaced from each other in the first direction DR1.

The pixel PXL may include a cathode electrode CE. The cathode electrode CE may be a common electrode for sub-pixels SP. Although not shown in the drawings, the cathode electrode CE may be a common electrode for the pixels PXL and other adjacent pixels PXL.

The cathode electrode CE may be extended in the first direction DR1. Although not shown, a portion of the cathode electrode CE may be extended in the first direction DR1, and another portion of the cathode electrode CE may be extended in the second direction DR2 and used as a common electrode for all sub-pixels SP. As such, the cathode electrode CE may have a variety of shapes.

The cathode electrode CE may be disposed at the same length as the anode electrode AE in the second direction DR2 as depicted in FIG. 4. For example, the cathode electrode CE may be patterned in the same process as the first to third anode electrodes AE1 to AE3 and may include the same conductive material.

The anode electrode AE and the cathode electrode CE may include a variety of conductive materials. The anode electrode AE and the cathode electrode CE may include one or more of reflective conductive materials and transparent conductive materials. However, the disclosure is not limited to thereto.

The cathode electrode CE may be spaced apart (e.g., in the second direction DR2) from the first to third anode electrodes AE1 to AE3.

The pixel PXL may include a light-emitting element LD. Each of the light-emitting elements LD may include a first semiconductor layer SCL1, an active layer AL, and a second semiconductor layer SCL2. The light-emitting element LD may further include an auxiliary layer AXL and an element insulation layer INF. The light-emitting element LD may further include a first element electrode EEL1 and a second element electrode EEL2.

The light-emitting element LD may include a light-emitting laminate in which the auxiliary layer AXL, the first semiconductor layer SCL1, the active layer AL, and the second semiconductor layer SCL2 are sequentially stacked.

The first semiconductor layer SCL1 disposed on the active layer AL may provide electrons to the active layer AL. The first semiconductor layer SCL1 may include, for example, at least one n-type semiconductor layer. For example, the first semiconductor layer SCL1 may include any one semiconductor material of gallium nitride (GaN), aluminum gallium nitride (AlGaN), indium gallium nitride (InGaN), aluminum nitride (AlN), and indium nitride (InN), and may be an n-type semiconductor layer doped with a first conductive dopant (or n-type dopant) such as silicon (Si), germanium (Ge), and tin (Sn). However, the materials forming the first semiconductor layer SCL1 are not limited thereto, and various other materials may form the first semiconductor layer SCL1. The first semiconductor layer SCL1 may include a gallium nitride (GaN) semiconductor material doped with the first conductive dopant (or n-type dopant).

The auxiliary layer AXL may include a semiconductor material that is not doped with impurities. For example, the auxiliary layer AXL may include the same semiconductor material as the first semiconductor layer SCL1, but may not include the first conductive dopant.

The first semiconductor layer SCL1 and the auxiliary layer AXL may form an n-type semiconductor layer.

The active layer AL may be disposed between the first semiconductor layer SCL1 and the second semiconductor layer SCL2, and may be an area where electrons and holes are recombined. As electrons and holes recombine in the active layer AL, light with a corresponding wavelength may be generated, transitioning to a lower energy level. The active layer AL may be formed as a single or multiple quantum well structure. In case that the active layer AL is formed as a multi-quantum well structure, units including a barrier layer, a strain reinforcing layer, and a well layer may be repeatedly stacked to form an active layer AL. However, embodiments of the active layer AL are not limited thereto.

The second semiconductor layer SCL2 may be disposed on the active layer AL and provide holes to the active layer AL. The second semiconductor layer SCL2 may include a different type of semiconductor layer from the first semiconductor layer SCL1. For example, the second semiconductor layer SCL2 may include at least one p-type semiconductor layer. For example, the second semiconductor layer SCL2 may include at least one semiconductor material of gallium nitride (GaN), aluminum gallium nitride (AlGaN), indium gallium nitride (InGaN), aluminum nitride (AlN), and indium nitride (InN), and may be a p-type semiconductor layer doped with a second conductive dopant (or p-type dopant) such as magnesium (Mg), zinc (Zn), calcium (Ca), strontium (Sr), and barium (Ba). However, the materials forming the second semiconductor layer SCL2 are not limited thereto, and various other materials may form the second semiconductor layer SCL2. The second semiconductor layer SCL2 may include a gallium nitride (GaN) semiconductor material doped with the second conductive dopant (or p-type dopant).

The first and second element electrodes EEL1 and EEL2 may be directed in the same direction (e.g., in the opposite direction to the third direction DR3. The first element electrode EEL1 may be disposed on a second semiconductor layer SCL2 exposed by the element insulation layer INF and may be electrically connected to the second semiconductor layer SCL2. The second element electrode EEL2 may be disposed on the first semiconductor layer SCL1 exposed by the element insulation layer INF and may be electrically connected to the first semiconductor layer SCL1.

The first and second element electrodes EEL1 and EEL2 may include a transparent electrode layer TEL capable of transmitting light, and a bonding electrode layer BEL containing eutectic metal. This will be described below with reference to the drawings after FIG. 7.

The element insulation layer INF may cover the outer surface of the light-emitting element LD (e.g., light-emitting laminate). The element insulation layer INF may prevent an electrical short circuit that may occur in case that the active layer AL is contact with conductive materials other than the first and second semiconductor layers (SCL1 and SCL2). The element insulation layer INF may include a transparent insulating material. The element insulation layer INF may expose bottom surfaces of the first and second element electrodes EEL1 and EEL2.

The light-emitting element LD may be disposed on the anode electrode AE and the cathode electrode CE. The light-emitting element LD may include a first light-emitting element LD1 included in the first sub-pixel SP1, a second light-emitting element LD2 included in the second sub-pixel SP2, and a third light-emitting element LD3 included in the third sub-pixel SP3.

The first to third light-emitting elements LD1 to LD3 may be spaced apart in the first direction DR1 and may be disposed in the first direction DR1.

The first light-emitting element LD1 may be disposed on the first portion of the first anode electrode AE1 and the cathode electrode CE. The second light-emitting element LD2 may be disposed on a second portion of the second anode electrode AE2 and a second portion of the cathode electrode CE. The third light-emitting element LD3 may be disposed on a third portion of the third anode electrode AE3 and the cathode electrode CE.

The plane (e.g., plan view) of the disclosure may be defined based on the plane on which a substrate SUB is disposed, as a direction extended in the first direction DR1 and the second direction DR2. The third direction DR3 may be a thickness direction of the substrate SUB, and the third direction DR3 may be a light-emitting direction of the display device DD.

Referring to FIG. 6, the cross-sectional structure of the pixel PXL including the first to third sub-pixels SP1 to SP3 is shown.

The display device DD including the pixel PXL according to an embodiment may be disposed on the substrate SUB and may include a pixel circuit layer PCL including the pixel circuit PXC.

The pixel circuit PXC may include a first pixel circuit PXC1 to drive the first sub-pixel SP1 (or first light-emitting element LD1) and electrically connected to the first light-emitting element LD1 (or first anode electrode AE1), a second pixel circuit PXC2 to drive the second sub-pixel SP2 (or second light-emitting element LD2) and electrically connected to the second light-emitting element LD2 (or second anode electrode AE2), and the third pixel circuit PXC3 to drive the third sub-pixel SP3 (or third light-emitting element LD3) and electrically connected to the third light-emitting element LD3 (or third anode electrode AE3).

The display element layer DPL may include the first to third light-emitting elements LD1 to LD3 that are electrically connected to the first to third pixel circuits PXC1 to PXC3, respectively. According to embodiments, each of the first to third light-emitting elements LD1 to LD3 may be disposed in the light-emitting area EMA of each of the first to third sub-pixels SP1 to SP3.

The light functional layer LFL may be disposed on the display element layer DPL.

The light functional layer LFL may include a capping layer CPL, an upper bank BNK_Q, a reflective layer RFL, light conversion pattern layers CCP1 and CCP2, a light scattering pattern layer LSP, an optical layer LRL, a color filter CF, and a light-blocking pattern layer LBP.

The capping layer CPL may be disposed on the display element layer DPL. The capping layer CPL may protect components disposed in the lower portion of the capping layer CPL, such as light-emitting elements LD, from external moisture. The capping layer CPL may include an inorganic material.

The upper bank BNK_Q may be disposed on the capping layer CPL. The upper bank BNK_Q may be disposed in a non-light-emitting area NEMA which is disposed between adjacent the light-emitting areas EMA. The upper bank BNK_Q may form an opening in which the light conversion pattern layers CCP1 and CCP2 and the light scattering pattern layer LSP are disposed. The upper bank BNK_Q may include a shading material to prevent light mixing between adjacent sub-pixels SP. In other embodiments, the upper bank BNK_Q may include an organic material. However, the embodiments are not necessarily limited to a particular example.

The reflective layer RFL may be disposed on the side of the upper bank BNK_Q and disposed in the light-emitting area EMA. The reflective layer RFL reflects the incident light, thereby improving the emission efficiency. The reflective layer RFL may include a light-reflective material. However, embodiments are not necessarily limited thereto.

The first and second light conversion pattern layers CCP1 and CCP2 may be disposed in the opening formed by the upper bank BNK_Q and may be disposed in the light-emitting area EMA. The first and second light conversion pattern layers CCP1 and CCP2 may be disposed in the first sub-pixel SP1 and the second sub-pixel SP2, respectively. The first and second light conversion pattern layers CCP1 and CCP2 may include first and second color conversion particles QD1 and QD2, respectively. The first and second light conversion pattern layers CCP1 and CCP2 may include organic matrix materials in which the first and second color conversion particles QD1 and QD2 may be dispersed. The first and second light conversion pattern layers CCP1 and CCP2 may further include scattering particles.

The light scattering pattern layer LSP may be disposed in the opening formed by the upper bank BNK_Q and may be disposed within the light-emitting area EMA. The light scattering pattern layer LSP may include scattering particles SCT. The light scattering pattern layer LSP may include an organic matrix material in which scattering particles SCT may be dispersed.

The optical layer LRL may be disposed on the upper bank BNK_Q, the reflective layer RFL, the first and second light conversion pattern layers CCP1 and CCP2, and the light scattering pattern layer LSP.

The optical layer LRL may be a low-refractive layer. The optical layer LRL may have a lower refractive index than the first and second light conversion pattern layers CCP1 and CCP2. Accordingly, the optical layer LRL may refract or totally reflect the light according to the angle of incidence of the light. The optical layer LRL may provide light that has passed through the first and second light conversion pattern layers CCP1 and CCP2 again to the first and second light conversion pattern layers CCP1 and CCP2. Accordingly, the optical conversion efficiency of the first and second light conversion pattern layers CCP1 and CCP2 may be improved.

Color filters CF may be disposed on the optical layer LRL. The color filters CF may be disposed in the light-emitting area EMA. The color filters CF may include a first color filter CF1 included in the first sub-pixel SP1, a second color filter CF2 included in the second sub-pixel SP2, and a third color filter CF3 included in the third sub-pixel SP3.

The color filters CF may include dyes or pigments that selectively transmit light of a color. For example, a first color filter CF1 may selectively transmit light of the first color, a second color filter CF2 may selectively transmit light of a second color, and a third color filter CF3 may selectively transmit light of a third color.

The light-blocking pattern layer LBP may be disposed in the non-light-emitting area NEMA and may reduce the risk of color mixing between sub-pixels SP. The light-blocking pattern layer LBP may include a variety of light-shielding materials (e.g., black matrix, carbon black, etc.), and the first to third color filters CF1 to CF3 may be formed to overlap in the third direction DR3.

Referring to FIGS. 7 to 9, the light-emitting element LD and conductive portions electrically connected to the light-emitting element LD may be disposed on the substrate SUB (or pixel circuit layer PCL).

The light-emitting element LD may be disposed on the anode electrode AE and the cathode electrode CE, and may be a flip-chip type light-emitting element.

The anode electrode AE and the cathode electrode CE may be patterned to be spaced apart from each other on a substrate (or pixel circuit layer PCL).

The display device DD may include an intermediate electrode ME.

The intermediate electrode ME may be disposed on the anode electrode AE and the cathode electrode CE. The intermediate electrode ME may include a first intermediate electrode ME1 on the anode electrode AE and a second intermediate electrode ME2 on the cathode electrode CE.

The intermediate electrode ME may be partially disposed on a portion of the upper surface of each of the anode electrode AE and the cathode electrode CE. The intermediate electrode ME may be partially patterned on a portion of the upper surface of each of the anode electrode AE and the cathode electrode CE.

The intermediate electrode ME may expose at least a portion of the upper surface of each of the anode electrode AE and the cathode electrode CE. For example, the first intermediate electrode ME1 may expose at least a portion of the upper surface of the anode electrode AE. The second intermediate electrode ME2 may expose at least a portion of the upper surface of the cathode electrode CE.

The lower surface of the intermediate electrode ME may be in contact with the upper surface of the anode electrode AE and the cathode electrode CE, respectively. The side surface of a portion (e.g., the first part) of the intermediate electrode ME may be opposite the side surface of another portion of the intermediate electrode ME (e.g., the second part).

The intermediate electrode ME may be partially disposed on the upper surface of each of the anode electrode AE and the cathode electrode CE, which forms a concavo-convex structure. For example, the intermediate electrode ME may form multiple protruding portions on the upper surface of each of the anode electrode AE and the cathode electrode CE. The intermediate electrode ME may be referred to as a concavo-convex metal part.

The intermediate electrode ME may transfer the light-emitting element LD onto a pixel circuit layer PCL based on a eutectic bonding process using eutectic metal formed on at least a portion of the light-emitting element LD. The intermediate electrode ME may include one or more of copper (Cu), gold (Au), and silver (Ag). However, the disclosure is not limited thereto.

The intermediate electrode ME may be patterned in various shapes on the anode electrode AE and the cathode electrode CE in a plan view.

For example (see FIG. 8), the intermediate electrode ME may have an island shape in a plan view and may include multiple intermediate electrodes ME spaced apart from each other. Each of the plurality of intermediate electrodes ME may be isolated from each other. Multiple intermediate electrodes ME may be arranged in a matrix structure based on the first direction DR1 and the second direction DR2. Multiple intermediate electrodes ME may be arranged according to a tiled structure. Accordingly, the intermediate electrode ME may expose the anode electrode AE and the cathode electrode CE in the area between multiple intermediate electrodes ME.

In another example (see FIG. 9), the intermediate electrode ME may have a mesh shape in a plan view. For example, the intermediate electrode ME may include a first portion extending in the first direction DR1 and a second portion extending in a second direction DR2 that is different from the first direction DR1, and the first and second portions may intersect each other at multiple positions. Accordingly, the intermediate electrode ME may expose the anode electrode AE and the cathode electrode CE in each of the openings OPN formed by the mesh shape.

Each of the first and second element electrodes EEL1 and EEL2 of the light-emitting element LD may include a bonding electrode layer BEL and a transparent electrode layer TEL. The first element electrode EEL1 may include a first bonding electrode layer BEL1 and a first transparent electrode layer TEL1. The second element electrode EEL2 may include a second bonding electrode layer BEL2 and a second transparent electrode layer TEL2.

The bonding electrode layer BEL may be disposed on the anode electrode AE and the cathode electrode CE. The bonding electrode layer BEL may be disposed on the intermediate electrode ME.

The bonding electrode layer BEL may include a first bonding electrode layer BEL1 covering the anode electrode AE and the first intermediate electrode ME1 and a second bonding electrode layer BEL2 covering the cathode electrode CE and the second intermediate electrode ME2.

The first bonding electrode layer BEL1 may be disposed between the anode electrode AE and the first transparent electrode layer TEL1. The second bonding electrode layer BEL2 may be disposed between the cathode electrode CE and the second transparent electrode layer TEL2.

The bonding electrode layer BEL may be in contact with at least a portion of each of the anode electrode AE and the cathode electrode CE. For example, the first bonding electrode layer BEL1 may be directly adjacent to some area of the anode electrode AE exposed by the first intermediate electrode ME1. The second bonding electrode layer BEL2 may be directly adjacent to some area of the cathode electrode CE exposed by the second intermediate electrode ME2.

The first bonding electrode layer BEL1 may be electrically connected to the first intermediate electrode ME1 and the anode electrode AE. The second bonding electrode layer BEL2 may be electrically connected to the second intermediate electrode ME2 and the cathode electrode CE.

The bonding electrode layer BEL may be in contact with the inner side surface of the intermediate electrode ME. For example, the first bonding electrode layer BEL1 may be directly adjacent to the inner side surface of the first intermediate electrode ME1. The second bonding electrode layer BEL2 may be directly adjacent to the inner side surface of the second intermediate electrode ME2.

The bonding electrode layer BEL may fill at least a portion of the openings OPN formed by the intermediate electrode ME. For example, during the bonding process of a light-emitting element LD, at least a portion of the bonding electrode layer BEL may be melted, and the bonding electrode layer BEL may be provided in the spaces formed by the intermediate electrode ME.

The bonding electrode layer BEL may include a conductive material suitable for eutectic bonding processes. The bonding electrode layer BEL may include a metallic material with a relatively low melting point. For example, a bonding electrode layer BEL may have a lower melting point than an intermediate electrode ME. For example, the bonding electrode layer BEL may include a SnAgCu alloy. However, disclosure is not limited to this example.

The bonding electrode layer BEL may cover more than a certain percentage of the upper surface of each of the anode electrode AE and the cathode electrode CE.

For example, a first bonding electrode layer BEL may cover an area of more than 30% of the upper surface of the anode electrode AE (e.g., an area of 30% to 100%) and may fill the opening OPN formed by the first intermediate electrode ME1 overlapping an area of 30% or more of the upper surface of the anode electrode AE (e.g., an area of 30% to 100%).

For example, a second bonding electrode layer BEL may cover an area of more than 30% of the upper surface of the cathode electrode CE (e.g., an area of 30% to 100%) and may fill the opening OPN formed by the second intermediate electrode ME2 overlapping an area of 30% or more of the upper surface of the cathode electrode CE (e.g., an area of 30% to 100%).

It may be determined that in the inspection step of the manufacturing process of the display device DD, the light-emitting element LD has been transferred normally onto the pixel circuit layer PCL, and it may be understood that the light-emitting element LD has been normally electrically connected to the anode electrode AE and the cathode electrode CE.

The transparent electrode layer TEL may be disposed on the bonding electrode layer BEL. The transparent electrode layer TEL may include a first transparent electrode layer TEL1 disposed on a first bonding electrode layer BEL1 and a second transparent electrode layer TEL2 disposed on a second bonding electrode layer BEL2.

The transparent electrode layer TEL may include a transparent conductive material. For example, a transparent electrode layer TEL may include one or more of the following: Indium Tin Oxide (ITO) and Indium Zinc Oxide (IZO). However, the disclosure is not limited to this example.

The transparent electrode layer TEL may be electrically connected to the bonding electrode layer BEL. Accordingly, the electrical signal provided by the anode electrode AE and the cathode electrode CE may be applied to the light-emitting element LD.

The transparent electrode layer TEL adjacent to the bonding electrode layer BEL may be configured to transmit light. Accordingly, during the inspection process to determine whether the light-emitting element LD has been transferred normally, the degree to which the bonding electrode layer BEL has filled the openings OPN formed by the intermediate electrode ME may be readily determined visually.

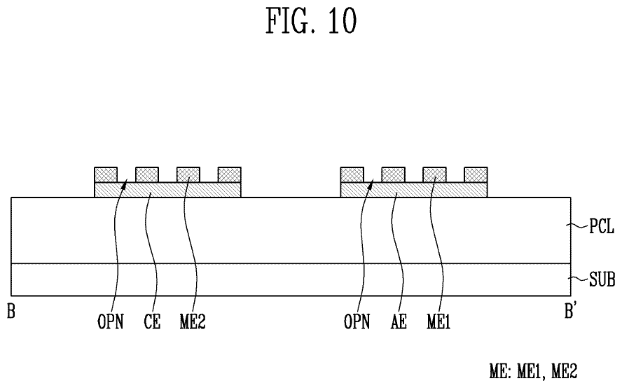

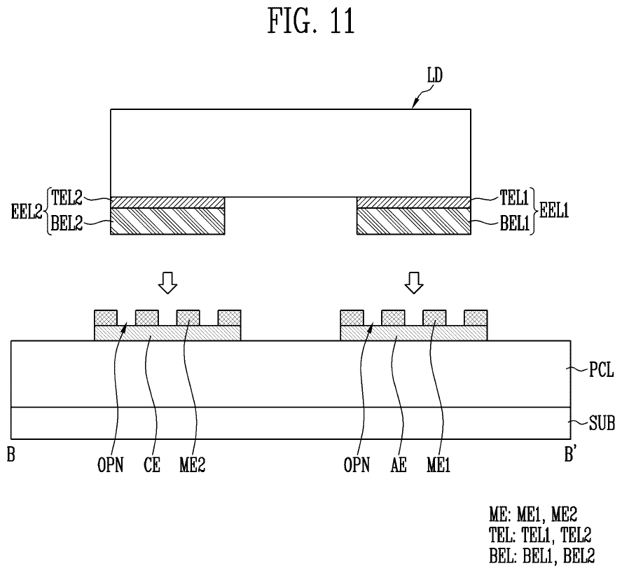

Hereinafter, a method of manufacturing a display device DD according to an embodiment will be described with reference to FIG. 10 to FIG. 14. For the convenience of explanation, information that may overlap the foregoing description may be briefly explained or may not be repeated.

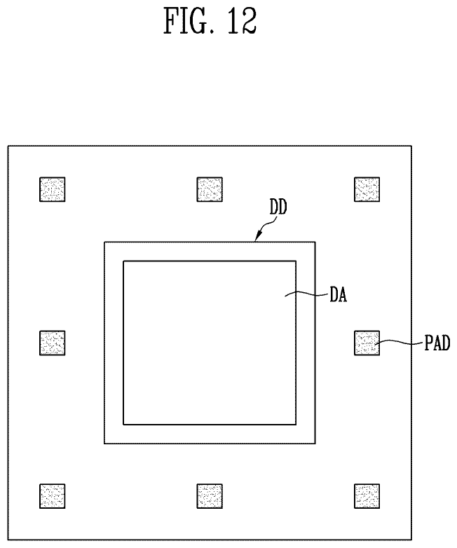

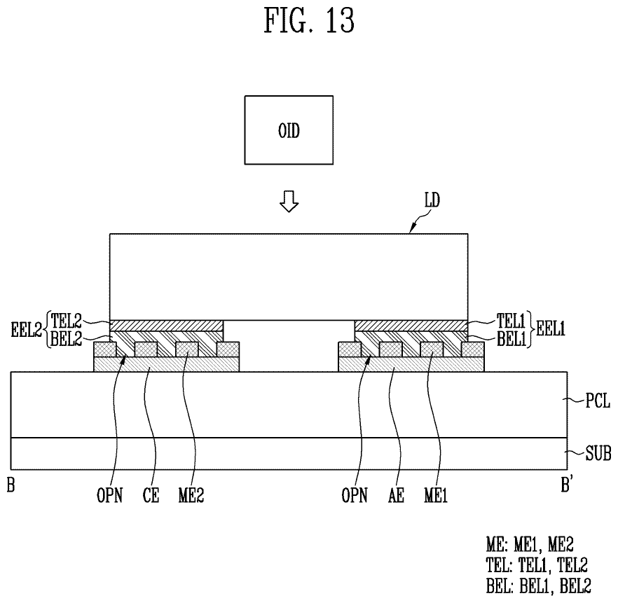

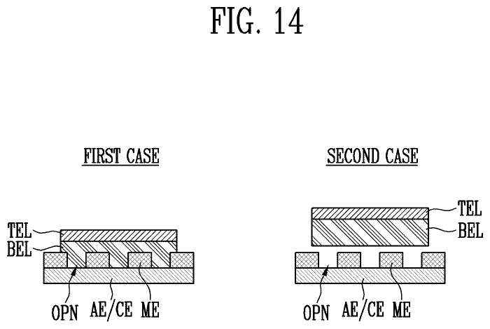

FIG. 10, FIG. 11, FIG. 13, and FIG. 14 are schematic cross-sectional diagrams for respective process steps schematically illustrating a method of manufacturing a display device according to an embodiment. FIG. 12 is a schematic plan view schematically illustrating an inspection step for a display device in a method of manufacturing the display device according to an embodiment. For the convenience of explanation, FIG. 10, FIG. 11, FIG. 13, and FIG. 14 are shown on the basis of the cross-sectional structure described with reference to FIG. 7.

Referring to FIG. 10, a substrate SUB may be provided, and a pixel circuit PXC may be formed by patterning a semiconductor layer, a conductive layer, and an insulation layer on the substrate SUB, and a pixel circuit layer PCL may be provided accordingly. An anode electrode AE and a cathode electrode CE are patterned on the pixel circuit layer PCL, and the intermediate electrode ME covering the anode electrode AE and cathode electrode CE may be patterned.

A conductive layer or an insulation layer on the substrate SUB may be formed on the basis of a conventional process for manufacturing semiconductor devices. For example, the conductive layer or the insulation layer disposed on the substrate SUB may be formed by photolithography processes, may be etched by various methods (wet etching, dry etching, etc.), and may be deposited by various methods (sputtering, chemical vapor deposition, etc.). The disclosure is not necessarily limited thereto.

The first intermediate electrode ME1 may be patterned so that the upper surface of the anode electrode AE is partially exposed. Accordingly, the first intermediate electrode ME1 may form a concavo-convex structure protruding from the upper surface of the anode electrode AE.

The second intermediate electrode ME2 may be patterned so that the upper surface of the cathode electrode CE is partially exposed. Accordingly, the second intermediate electrode ME2 may form a concavo-convex structure protruding from the upper surface of the cathode electrode CE.

Referring to FIG. 11, a light-emitting element LD may be disposed (e.g., transferred) on a substrate SUB (or pixel circuit layer PCL).

The light-emitting element LD may be transferred using a eutectic bonding process.

The light-emitting elements LD may be transferred to allow the lower portion of the first and second element electrodes EEL1 and EEL2 to be directed to the lower portion so that the light-emitting element LD has the structure of a flip-chip type light-emitting element.

The bonding electrode layers BEL may be melted to fill at least a portion of the openings OPN (or spaces) formed by the intermediate electrodes ME. Accordingly, the bonding electrode layers BEL may bond the light-emitting element LD onto the anode electrode AE, the cathode electrode CE, and the intermediate electrode ME.

In case that the light-emitting elements LD are normally bonded to the anode electrode AE and the cathode electrode CE, the bonding electrode layers BEL may fill the openings OPN formed by the intermediate electrodes ME in a relatively large area. Accordingly, the light-emitting elements LD may be normally electrically connected to the anode electrode AE and the cathode electrode CE.

Referring to FIGS. 12 to 14, an inspection process may be performed to determine whether the light-emitting element LD of the display device DD has been normally bonded.

In this step, a pad PAD for the inspection process of the light-emitting element LD may be disposed on the periphery of the display device DD. The pad PAD may be electrically connected to an optical inspection device OID.

The optical inspection device OID may acquire image information about the light-emitting element LD and underlying layers of the light-emitting element LD. The optical inspection device OID may acquire image information showing the extent to which the first bonding electrode layer BEL1 covers the anode electrode AE and the first intermediate electrode ME1, and may acquire image information showing the extent to which the second bonding electrode layer BEL2 covers the cathode electrode CE and the second intermediate electrode ME2.

The image information may be provided through a transparent electrode layer TEL. Since the transparent electrode layer TEL adjacent to the bonding electrode layer BEL may transmit light, the aforementioned image information may be acquired appropriately.

IT may be determined whether the first bonding electrode layer BEL1 is normally bonded to the anode electrode AE and the first intermediate electrode ME1 based on the extent to which the first bonding electrode layer BEL1 fills the opening OPN formed by the first intermediate electrode ME1. For example, in case that the first bonding electrode layer BEL1 fills an area including the opening OPN formed by the first intermediate electrode ME1 by a selected range or more (e.g., more than 30%), it may be determined that the first bonding electrode layer BEL1 is normally bonded to the anode electrode AE and the first intermediate electrode ME1.

IT may be determined whether the second bonding electrode layer BEL2 has been normally bonded to the cathode electrode CE and the second intermediate electrode ME2 based on the extent to which the second bonding electrode layer BEL2 fills the opening OPN formed by the second intermediate electrode ME2. For example, in case that the second bonding electrode layer BEL2 fills an area including the opening OPN formed by the second intermediate electrode ME2 by a selected range or more (e.g., more than 30%), it may be determined that the second bonding electrode layer BEL2 has been normally bonded to the cathode electrode CE and the second intermediate electrode ME2.

For example, referring to FIG. 14, a first case FIRST CASE shows a structure in which the light-emitting element LD has been normally bonded to the anode electrode AE, the cathode electrode CE, and the intermediate electrode ME. A second case SECOND CASE shows a structure in which the light-emitting element LD has not been normally bonded to the anode electrode AE, the cathode electrode CE, and the intermediate electrode ME.

In case that the light-emitting element LD is transferred normally, the bonding electrode layer BEL may sufficiently fill the opening OPN formed by the intermediate electrode ME. In comparison, in case that the light-emitting element LD is not transferred normally, the bonding electrode layer BEL may not be able to adequately fill the opening OPN formed by the intermediate electrode ME.

The inspection process for the light-emitting element LD performed in this step may be carried out on the basis of these structural differences. In other words, according to an embodiment, the inspection process for the light-emitting element LD may be performed without light emission of the light-emitting element LD.

Experimentally, even in case that the light-emitting element LD is abnormally transferred, it may be relatively frequent for the abnormal light-emitting element to emit light intermittently. The reliability of the inspection process may be damaged, and there may be a risk that the quality of the display of the display device DD may be deteriorated.

However, according to an embodiment, in the process step prior to recognizing that the light-emitting element LD emits light, it may be determined based on visual information whether the light-emitting element LD is normally bonded without light emission of the light-emitting element LD. As a result, the reliability of the inspection process may be improved, which in turn may further improve the display quality of the display device DD.

Thereafter, additional layers such as the light functional layer LFL may be disposed on the light-emitting element LD, depending on an embodiment, and the display device DD according to the embodiment may be provided.

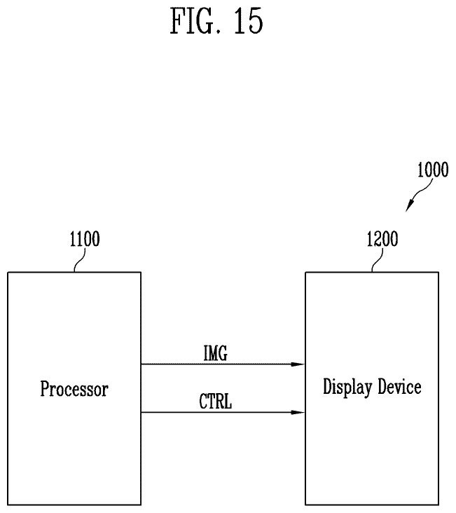

FIG. 15 is a schematic block diagram illustrating an embodiment of an electronic device.

Referring to FIG. 15, an electronic device 1000 may include a processor 1100 and a display device 1200. The electronic device 1000 may implement a display system.

The processor 1100 may perform a variety of tasks and calculations. In other embodiments, the processor 1100 may include an application processor, a graphics processor, a microprocessor, a central processing unit, and the like. The processor 1100 is electrically connected to other components of the electronic device 1000 via a bus system and may control them.

The processor 1100 may transmit image data IMG and a control signal CTRL to the display device 1200. The display device 1200 may display images based on image data IMG and the control signal CTRL. The display device 1200 may be configured in the same manner as the display device DD-described above.

The electronic device 1000 may include a computing system that provides image display functions such as a smart watch, a mobile phone, a smart phone, a portable computer, a tablet personal computer, a watch phone, an automotive display, smart glasses, a portable multimedia player (PMP), a navigation device, an ultra mobile personal computer (UMPC), etc. The electronic device 1000 may include at least one of the following: a Head Mounted Display (HMD), a Virtual Reality (VR) device, a Mixed Reality (MR) device, or an Augmented Reality (AR) device.

According to an embodiment, the electronic device 1000 may further include a memory device, a storage device, an input/output (I/O) device, and a power supply.

The memory device may store data needed to perform the operation of the electronic device 1000. The memory device may function as a working memory and/or a buffer memory for the processor. For example, the memory device may include one or more volatile memory devices such as a dynamic random access memory (DRAM) device, a static random access memory (SRAM) device, and a mobile DRAM device.

The storage device may store data in response to control signals or data from the processor. The storage device may include one or more non-volatile storages to retain the data even when the electronic device 1000 is powered off. In some embodiments, the storage device may include a solid state drive (SSD), a hard disk drive (HDD), a CD-ROM, or the like.

The I/O device may include input devices such as a keyboard, a keypad, a touchpad, a touch screen, and a mouse, and output devices such as a speaker and a printer. In an embodiment, the display device 1210, 1220 may be included in the I/O device.

The power supply may supply power needed to perform the operation of the electronic device 1000. For example, the power supply may be a power management integrated circuit (PMIC). In an embodiment, the power supply may supply power to the display device 1210, 1220.

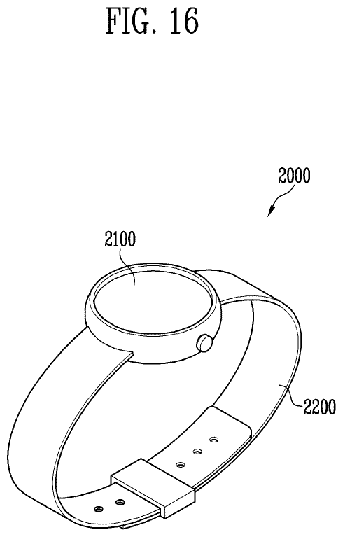

FIGS. 16 to 19 are perspective views illustrating examples of the application of the electronic device in FIG. 15.

Referring to FIG. 16, the electronic device 1000 of FIG. 15 may be applied to a smart watch 2000 including a display unit 2100 and a strap unit 2200.

The smart watch 2000 may be a wearable electronic device. For example, the smart watch 2000 may have a structure in which the strap unit 2200 is mounted on a user's wrist. Here, the electronic device 1000 and/or the display device 1200 may be applied to the display unit 2100 so that image data including time information may be provided to the user.

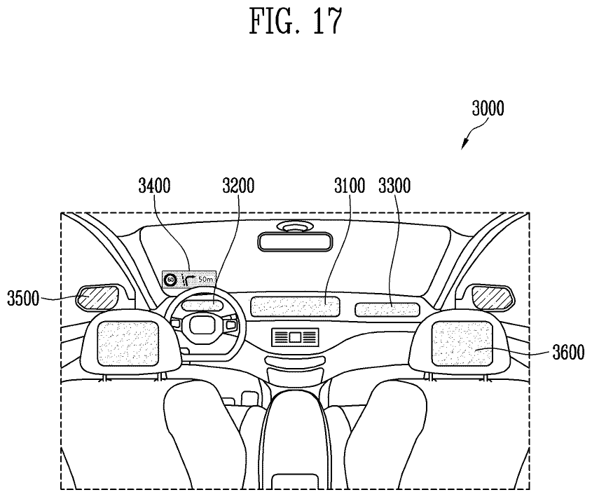

Referring to FIG. 17, the electronic device 1000 of FIG. 15 may be applied to an automotive electronic device 3000. Here, the automotive electronic device 3000 may include a computing system that is equipped inside and/or outside the vehicle to provide image data.

For example, the electronic device 1000 and/or display device 1200 may be applied to at least one of an infotainment panel 3100, a cluster 3200, a co-driver display 3300, a head-up display 3400, a side mirror display 3500, and a rear seat display 3600, which are provided in a vehicle.

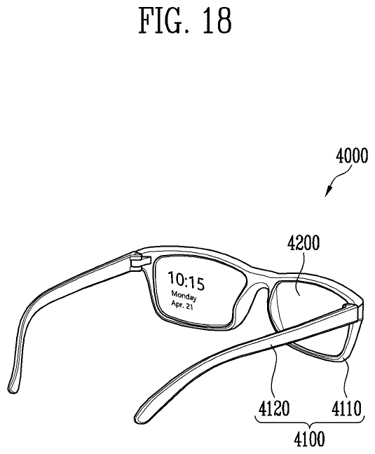

Referring to FIG. 18, the electronic device 1000 of FIG. 15 may be applied to smart glasses 4000. The smart glasses 4000 may be a wearable electronic device that may be worn on the user's head. For example, the smart glasses 4000 may be a wearable device for augmented reality.

The smart glasses 4000 may include a frame 4100 and a lens portion 4200. The frame 4100 may include a housing 4110 to support the lens portion 4200 and a leg portion 4120 for a user's wearing. The leg portion 4120 may be connected to the housing 4110 by means of a hinge, which may be folded or unfolded with respect to the housing 4110.

The frame 4100 may include a built-in battery, touch pad, microphone, camera, etc. The frame 4100 may include a built-in projector that outputs light, a built-in processor that controls a light signal, etc.

The lens portion 4200 may include an optical member that transmits light or reflects light. For example, the lens portion 4200 may include glass, transparent synthetic resin, etc.

In order for the user's eyes to perceive visual information, the lens portion 4200 may reflect the image by the light signal emitted from the projector of the frame 4100 by the back surface of the lens portion 4200 (e.g., the surface facing the user's eyes). For example, the user may recognize visual information such as time and date displayed on the lens portion 4200. Here, the projector and/or lens portion 4200 may be a kind of display device. The display device 1200 may be applied to the projector and/or lens portion 4200.

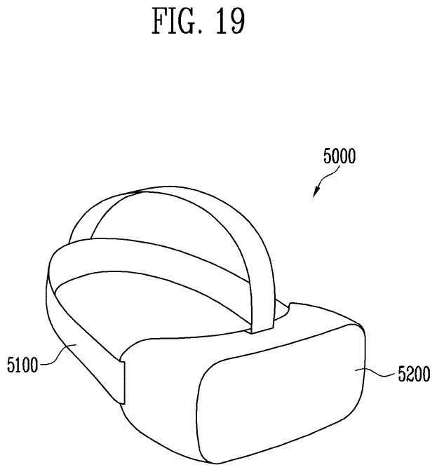

Referring to FIG. 19, the electronic device 1000 of FIG. 15 may be applied to a head-mounted display device 5000.

The head-mounted display device 5000 may be a wearable electronic device that may be worn on the user's head. For example, the head-mounted display device 5000 may be a wearable device for virtual reality or mixed reality.

The head-mounted display device 5000 may include a head-mounted band 5100 and a display storage case 5200. The head-mounted band 5100 may be connected to the display storage case 5200. The head-mounted band 5100 may include a horizontal band and/or a vertical band for fixing the head-mounted display device 5000 to the user's head. The horizontal band may be configured to surround a side portion of the user's head, and the vertical band may be configured to surround an upper portion of the user's head. However, embodiments are not limited to this example. For example, the head-mounted band 5100 may be implemented in the form of a frame, helmet, etc.

The display storage case 5200 may accommodate the electronic device 1000 and/or the display device 1200.

Although specific embodiments and applications have been described herein, other embodiments and variations may be derived from the above description. Accordingly, the idea of the disclosure is not limited to these embodiments, but extends to the appended claims, various obvious modifications, and equivalents.

What is claimed is:

1. A display device comprising:
a substrate;
an anode electrode and a cathode electrode, which are disposed on the substrate;
an intermediate electrode including a first intermediate electrode which is disposed on the anode electrode and exposes a portion of the anode electrode, and a second intermediate electrode which is disposed on the cathode electrode and exposes a portion of the cathode electrode; and
a light-emitting element including a first element electrode electrically connected to the anode electrode, and a second element electrode electrically connected to the cathode electrode,
wherein the first element electrode includes a first transparent electrode layer and a first bonding electrode layer disposed on the first transparent electrode layer,
the second element electrode includes a second transparent electrode layer and a second bonding electrode layer disposed on the second transparent electrode layer,
the first bonding electrode layer is disposed between the first transparent electrode layer and the first intermediate electrode and contacts the portion of the anode electrode exposed by the first intermediate electrode, and
the second bonding electrode layer is disposed between the second transparent electrode layer and the second intermediate electrode, contacts the portion of the cathode electrode exposed by the second intermediate electrode.

2. The display device of claim 1, wherein the first intermediate electrode is at least partially disposed on a portion of the anode electrode, and
the second intermediate electrode is at least partially disposed on a portion of the cathode electrode.

3. The display device of claim 2, wherein a side surface of a first portion of the intermediate electrode faces a side surface of a second portion of the intermediate electrode, and
the intermediate electrode forms a concavo-convex structure on the anode electrode and the cathode electrode.

4. The display device of claim 1, wherein the intermediate electrode includes one or more of copper (Cu), gold (Au), and silver (Ag).

5. The display device of claim 1, wherein the first bonding electrode layer is electrically connected to the first intermediate electrode and the anode electrode, and
the second bonding electrode layer is electrically connected to the second intermediate electrode and the cathode electrode.

6. The display device of claim 5, wherein the first bonding electrode layer is adjacent to an inner side surface of the first intermediate electrode, and
the second bonding electrode layer is adjacent to an inner side surface of the second intermediate electrode.

7. The display device of claim 6, wherein an opening is formed in the intermediate electrode, and
the first bonding electrode layer and the second bonding electrode layer fill at least a portion of the opening.

8. The display device of claim 1, wherein the first bonding electrode layer covers an area of more than about 30% of an upper surface of the anode electrode, and
the second bonding electrode layer covers an area of more than about 30% of an upper surface of the cathode electrode.

9. The display device of claim 1, wherein the first bonding electrode layer and the second bonding electrode layer have a lower melting point than a melting point of the intermediate electrode.

10. The display device of claim 1, wherein the first transparent electrode layer and the second transparent electrode layer include one or more of Indium Tin Oxide (ITO) and Indium Zinc Oxide (IZO).

11. The display device of claim 1, wherein the intermediate electrode includes a plurality of intermediate electrodes which are spaced apart from each other and arranged in a matrix shape, and have an island shape.

12. The display device of claim 1, wherein the intermediate electrode has a mesh shape, and includes first portions extending in a first direction and second portions extending in a second direction intersecting the first direction.

13. The display device of claim 1, wherein the light-emitting element is a flip-chip type light-emitting element.

14. A method of manufacturing a display device, the method comprising:
patterning an anode electrode and a cathode electrode on a substrate;
patterning a first intermediate electrode and a second intermediate electrode on the anode electrode and the cathode electrode, respectively;
disposing a light-emitting element including a first element electrode on the first intermediate electrode and a second element electrode on the second intermediate electrode; and
inspecting the light-emitting element,
wherein the patterning of the first intermediate electrode includes exposing a portion of the anode electrode by the first intermediate electrode,
the patterning of the second intermediate electrode includes exposing a portion of the cathode electrode by the second intermediate electrode, and
the inspecting of the light-emitting element includes determining whether or not the light-emitting element is normally disposed, without light emission of the light-emitting element.

15. The method of claim 14, wherein the patterning of the first intermediate electrode includes forming an opening by forming a concavo-convex structure by the first intermediate electrode, and
the patterning of the second intermediate electrode includes forming an opening by forming a concavo-convex structure by the second intermediate electrode.

16. The method of claim 15, wherein the light-emitting element includes a first element electrode including a first bonding electrode layer and a first transparent electrode layer and a second element electrode including a second bonding electrode layer and a second transparent electrode layer, and
the disposing of the light-emitting element includes:
melting the first bonding electrode layer to fill the opening on the anode electrode; and
melting the second bonding electrode layer to fill the opening on the cathode electrode.

17. The method of claim 16, wherein the inspecting of the light-emitting element includes acquiring, by an optical inspection device, image information which includes an image showing an extent to which the first bonding electrode layer covers the anode electrode and the first intermediate electrode and an image showing an extent to which the second bonding electrode layer covers the cathode electrode and the second intermediate electrode, and
the image information is provided by transmitting through the first transparent electrode layer and the second transparent electrode layer.

18. The method of claim 17, wherein the inspecting of the light-emitting element includes determining whether the first bonding electrode layer is normally bonded to the anode electrode and the first intermediate electrode, based on an extent to which the first bonding electrode layer fills the opening on the anode electrode.

19. The method of claim 18, wherein the determining of whether the first bonding electrode layer is normally bonded to the anode electrode and the first intermediate electrode includes determining that the first bonding electrode layer is normally bonded to a first anode electrode and the first intermediate electrode, in case that the first bonding electrode layer fills an area including the opening on the anode electrode beyond a selected range.

20. An electronic device, comprising:
a processor configured to provide input image data;
a display device configured to display an image based on the input image data, the display device including sub-pixel areas; and
a power supply configured to supply power to the display device,
wherein the display device comprises:
a substrate;
an anode electrode and a cathode electrode, which are disposed on the substrate;
an intermediate electrode including a first intermediate electrode which is disposed on the anode electrode and exposes a portion of the anode electrode, and a second intermediate electrode which is disposed on the cathode electrode and exposes a portion of the cathode electrode; and
a light-emitting element including a first element electrode electrically connected to the anode electrode, and a second element electrode electrically connected to the cathode electrode,
the first element electrode includes a first transparent electrode layer and a first bonding electrode layer disposed on the first transparent electrode layer,
the second element electrode includes a second transparent electrode layer and a second bonding electrode layer disposed on the second transparent electrode layer,
the first bonding electrode layer is disposed between the first transparent electrode layer and the first intermediate electrode and contacts the portion of the anode electrode exposed by the first intermediate electrode, and
the second bonding electrode layer is disposed between the second transparent electrode layer and the second intermediate electrode, contacts the portion of the cathode electrode exposed by the second intermediate electrode.
